(19) United States
(12) Patent Application Publication
(10) Pub. No.: US 2015/0048837 A1
(43) Pub. Date: Feb. 19, 2015

(54) METHOD OF MANAGING STATE OF CHARGE AND ELECTRONIC DEVICE THEREOF

(71) Applicant: Samsung Electronics Co., Ltd., Gyeonggi-do (KR)

(72) Inventors: Se-Won OH, Gyeonggi-do (KR); Won-Bae JUNG, Gyeonggi-do (KR)

(73) Assignee: Samsung Electronics Co., Ltd.

(21) Appl. No.: 14/445,648

(22) Filed: Jul. 29, 2014

(30) Foreign Application Priority Data
Aug. 19, 2013 (KR) 10-2013-0097896

(51) Int. Cl. G01R 31/36

(52) U.S. Cl. CPC G01R 31/3682; G01R 31/3606
USPC 324/427

(57) ABSTRACT

A method of managing a State of Charge (SoC) of a battery and an electronic device therefor are provided. The method includes verifying the charging remaining capacity of a first battery which is installed in the electronic device and comparing the verified charging remaining capacity of the first battery with a charging level of a second battery, which is received from a charging device through a local-area communication method, the second battery being charged in the charging device and the charging level of the second battery is verified by the charging device.

### PRIORITY

This application claims priority under 35 U.S.C. §119(a) to a Korean Patent Application filed in the Korean Intellectual Property Office on Aug. 19, 2013 and assigned Serial No. 10-2013-0097896, the entire disclosure of which is incorporated herein by reference.

### BACKGROUND OF THE INVENTION

1. Field of the Invention

The present invention generally relates to an electronic device having a battery, and more particularly, to a method of managing a State of Charge (SoC) of a battery and an electronic device thereof.

2. Description of the Related Art

Recently, as multimedia technologies have been developed, electronic devices, having various functions, have been released to the market. In general, these electronic devices have a convergence function for performing one or more complex functions.

The electronic devices are mainly mobile terminals classified roughly into so-called “smart phones”. Particularly, each of these mobile terminals has a large-screen display module of a touch type, and a high pixel camera module. Accordingly, in addition to a basic function for performing communication with a counterpart, each of the mobile terminals may photograph still pictures and moving pictures, and also may reproduce multimedia contents such as music and videos. Each of the mobile terminals may also perform web surfing by connecting to a network. These advanced electronic devices perform various convergence functions more quickly by using a high performance processor. Electronic devices have made such remarkable developments that now the main function for communicating with a counterpart is rather seen as an additional function.

On the other hand, in order to provide a high definition and performance service as well as the above-described functions, a usage time of a battery of the electronic device due to high current consumption is much decreased. Accordingly, a period for replacing the battery has been quickened. The electronic device typically has a separate charging device for charging a discharged battery; however, this charging device may not display an SoC of the battery accurately.

Therefore, there is a need to provide a user interface such that the user of the electronic device may intuitively verify an SoC of a battery which is being charged.

### SUMMARY OF THE INVENTION

An aspect of the present invention is to solve at least the above-mentioned problems and/or disadvantages and to provide at least the advantages described below.

An aspect of the present invention is to provide a method of managing an SoC of a battery and an electronic device therefor.

Another aspect of the present invention is to provide a user interface for intuitively verifying an SoC of a battery.

In accordance with an aspect of the present invention, an operation method of an electronic device is provided. The operation method includes verifying the charging remaining capacity of a first battery which is being installed in the electronic device and comparing the verified charging remaining capacity of the first battery with a charging level of a second battery, which is received from a charging device through a local-area communication method, wherein the second battery is being charged in the charging device and wherein the charging level of the second battery is verified by the charging device.

In accordance with another aspect of the present invention, an electronic device is provided. The electronic device includes a battery charging unit for verifying the charging remaining capacity of a first battery which is being installed in the electronic device, a wireless communication device for receiving a charging level of a second battery from a charging device through a local-area communication method, and a processor for comparing the verified charging remaining capacity of the first battery with the received charging level of the second battery, wherein the second battery is being charged in the charging device and wherein the charging level of the second battery is verified by the charging device.

### BRIEF DESCRIPTION OF THE DRAWINGS

The above and other aspects, features and advantages of certain embodiments of the present invention will be more apparent from the following detailed description taken in conjunction with the accompanying drawings, in which:

FIG. 1 is an exploded perspective view illustrating a structure of an electronic device having a battery according to an embodiment of the present invention;

FIG. 2 is a perspective view illustrating a structure of a battery according to an embodiment of the present invention;

FIG. 3 is a perspective view illustrating a structure of a charging device according to an embodiment of the present invention;

FIG. 4 is a block diagram illustrating a configuration of a charging device for charging a battery according to an embodiment of the present invention;

FIG. 5 is a graph of charging progress of a charging device according to an embodiment of the present invention;

FIG. 6 is a block diagram illustrating a configuration of an electronic device according to an embodiment of the present invention;

FIG. 7 is a flowchart illustrating an operation process of an electronic device according to an embodiment of the present invention;

FIG. 8 is a flowchart illustrating an operation process of an electronic device according to another embodiment of the present invention;

FIG. 9 is a flowchart illustrating an operation process of an electronic device according to another embodiment of the present invention;

FIG. 10 is a flowchart illustrating an operation process of an electronic device according to another embodiment of the present invention;

FIG. 11 illustrates a screen for displaying an SoC of a battery according to an embodiment of the present invention;

FIGS. 12A and 12B illustrate screens for displaying an SoC of a battery in an electronic device to which a flip cover is applied according to an embodiment of the present invention;

FIGS. 13 and 14 illustrate screens for displaying a battery SoC message according to an embodiment of the present invention; and

FIG. 15 illustrates a screen for displaying a battery readjustment request message according to an embodiment of the present invention.

### DETAILED DESCRIPTION OF EMBODIMENTS OF THE PRESENT INVENTION

Embodiments of the present invention will be described hereinbelow with reference to the accompanying drawings. In the following description, well-known functions or constructions are not described in detail since they would obscure the invention in unnecessary detail.

In explaining various embodiments of the present invention, a touch screen may be a display unit. A description will be given for, but is not limited to, an electronic device including a removable battery. For example, the electronic device may be any one of various devices, each of them including a removable battery, such as a Personal Digital Assistant (PDA), a laptop computer, a mobile phone, a smart phone, a netbook, a Mobile Internet Device (MID), a Ultra Mobile Personal Computer (UMPC), a tablet PC, a note PC, a watch, a navigation device, and a Moving Picture Experts Group (MPEG) layer 3 (MP3) player.

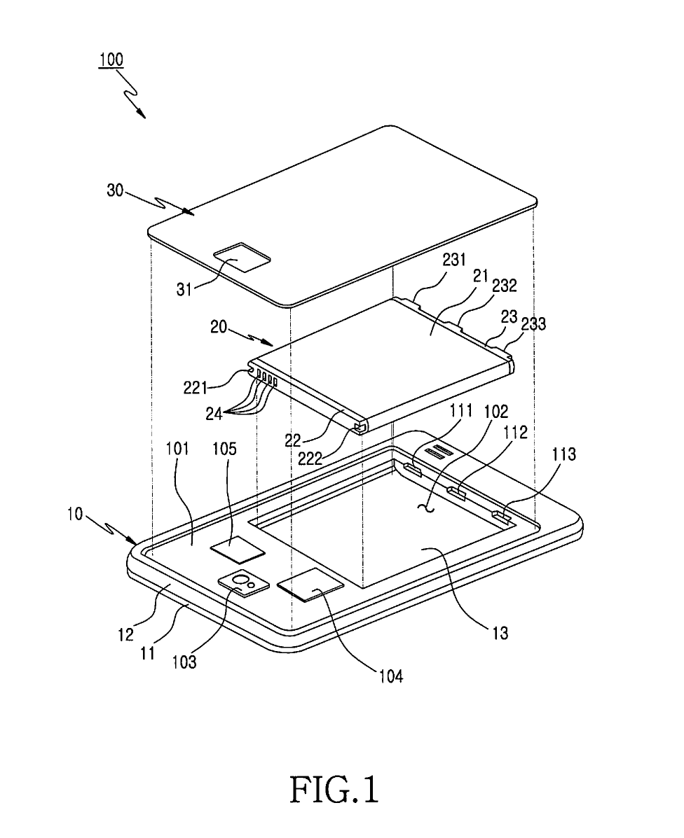

FIG. 1 is an exploded perspective view illustrating a structure of an electronic device having a battery according to an embodiment of the present invention.

Referring to FIG. 1, the electronic device 100 includes a body 10, a battery 20 removably installed in a rear surface of the body 10, and a cover 30, which is mounted in a part of the rear surface of the body 10, for protecting the various internal components. The cover 30 protects the battery 20 from being exposed to the outside or becoming separated from the electronic device 100. An opening 31, which allows a component (e.g., a camera module 103) to pass through, may be provided in the cover 30. Also, the cover 30 is removably installed on the body 10.

The body 10 of the electronic device 100 has a structure in which an upper case frame 11 and a lower case frame 12 are combined with each other. The body 10 accommodates various electronic components. Although it is not shown in FIG. 1, a large-screen display module for data input and output may be installed on a front surface of the electronic device 100. This display module may be a touch screen including a touch sensor for receiving data input.

A cover mounting part 101 is formed in a rear surface of the electronic device 100. Various components may be exposed on the cover mounting part 101. For example, these components are installed to be removable when using the electronic device 100. The components include not only the battery 20 but also a Subscriber Identity Module (SIM) mounting part 104 for mounting a SIM card, a memory card mounting part 105 for mounting a small memory card, etc. Also, the camera module 103 which must be exposed to the outside to photograph an object may be installed on the cover mounting part 101 of the electronic device 100.

The cover mounting part 101 is typically configured to be identical in size and shape to an external surface of the body 10 (particularly, the lower case frame 12) when being mounted on the body 10. Accordingly, it is preferable that the cover mounting part 101 is formed as a groove type in which a groove has a depth equal to a thickness of the cover 30. Accordingly, when the cover 30 is mounted on the lower case frame 12 of the electronic device 100, the cover 30 and the lower case frame 12 are in the same plane. Although it is not shown in FIG. 1, a plurality of holding projections may be formed at certain intervals along an edge of the cover 30. Also, a plurality of holding grooves may be formed in the cover mounting part 101 of the body 10. The cover 30 is thus fixed to the cover mounting part 101 by fitting the holding projections to the holding grooves.

In accordance with an embodiment of the present invention, a battery installing part 102, which is formed to be lower than a surface of the cover mounting part 101, for mounting the battery 20 may be formed in the cover mounting part 101. A lower side of the battery installing part 102 is in a state where it is spaced apart from the other components such as a display module disposed in an opposite direction by a separate flat surface plate 13. Both sides of the battery installing part 102 may be formed as a structure for supporting both sides of the battery 20 during an injection molding process of the upper case frame 11 and the lower case frame 12.

The battery 20 includes a battery cell 21 and first and second supports 22 and 23 formed to support the battery cell 21 at both ends of the battery cell 21. These first and second supports 22 and 23 may be formed as insulators of plastic materials to support the battery cell 21.

The first support 22 includes a plurality of terminals 24 which are electrically connected with the battery cell 21 in the battery 20and exposed to the outside, and are electrically connected with a connector (not shown) which is installed in the battery installing part 102 of the body 10. These terminals 24 include, but are not limited to, four terminals. Also, concave grooves 221 and 222 are formed in, but is not limited to, both ends of the first support 22. The concave grooves 221 and 222 may guide the battery 20 to be installed and simultaneously prevent the battery 20 from being separated by mating with projections provided in the battery installing part 102. However, it is contemplated that projections can be formed on both ends of the first support 22 and concave grooves can be formed in corresponding positions of the battery installing part 102 of the body 10.

In accordance with an embodiment of the present invention, a plurality of mounting projections 231 to 233 protrude at a certain interval on the second support 23 of the battery 20. Accordingly, when the battery 20 is installed on the battery installing part 102 of the body 10, the mounting projections 231 to 233 may be mounted in recesses 111 to 113, respectively, which are formed in corresponding positions of borders of the battery installing part 102. Thus, when the battery 20 is installed on the battery installing part 102, it is supported by a structure in which the projections formed on the battery installing part 102 of the body 10 are combined with the concave grooves 221 and 222 of the first support 22. Because the plurality of mounting projections 231 to 233 of the second support 23 are held in the recesses 111 to 113 formed in corresponding positions of the battery installing part 102 of the body 10, the battery 20 itself may not have an influence on the thin surface plate 13 disposed on a lower surface of the battery installing part 102.

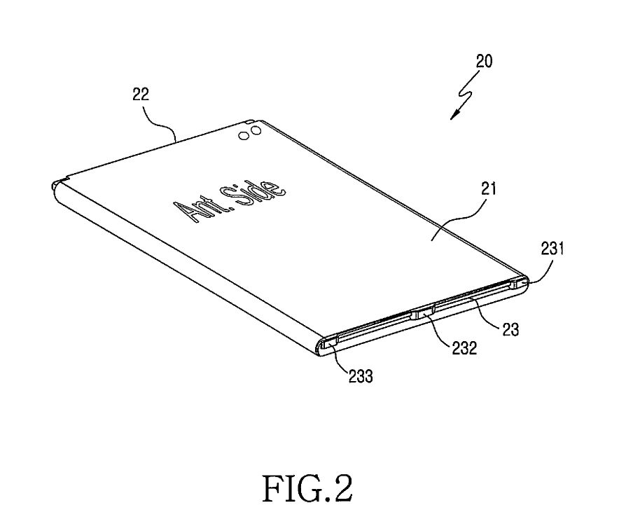

FIG. 2 is a perspective view illustrating a structure of a battery according to an embodiment of the present invention.

Referring to FIGS. 1 and 2, the battery 20 includes the battery cell 21 and the first and second supports 22 and 23 installed at both the ends of the battery cell 21. The plurality of mounting projections 231 to 233 are formed in a certain shape on the second support 23. Accordingly, the battery 20 may be installed so that the projections 231 to 233 are held in the recesses 111 to 113 formed in the battery installing part 102 of the body 10.

Although it is not shown in FIG. 2, an embedded antenna device for wireless communication, such a Near Field Communication (NFC), Wireless Fidelity (Wi-Fi) communication and Bluetooth Communication for wireless communication may be installed in the battery 20. The embedded antenna device may be, but is not limited to, a loop antenna device which is installed in various shapes such as a circle, a polygon, etc. For example, an NFC antenna device may be at least one of various antenna devices, such as a dipole antenna device, a monopole antenna device, a helical antenna device, a microstrip patch antenna device, an embedded antenna device of a plate structure such as a PIFA device, etc.

In accordance with an embodiment of the present invention, in an NFC antenna device, a carrier molded as an insulator such as polycarbonate is installed in the battery 20. The NFC antenna device may have configuration in which an antenna radiator of a circuit pattern shape for performing wireless transmission and reception in a specific frequency band is loaded on an upper surface of this carrier. The NFC antenna device configured by this type may be designed to operate through the plurality of terminals 24 which are electrically connected with a connector installed in the battery installing part 102 of the body 10 when the battery 20 is installed in the battery installing part 102 of the electronic device 100.

The NFC antenna device installed in the battery 20 includes an antenna radiator configured as a certain pattern. The NFC antenna device is electrically connected with a feeding portion (not shown) of a circuit board by an electric connection means on an upper portion of the antenna radiator. This electric connection means may be at least one of various conductive materials such as a well-known conductive tape having a certain thickness, as well as a C-clip. A connection part located at one end of the C-clip electrically makes contact and connects with the feeding portion of the circuit board, and an elastic part located at the other end of the C-clip comes in contact with a terminal part of the antenna radiator. In accordance with this type, the NFC antenna device receives current from the above-described feeding portion, resonates by magnetic inductive coupling, and transmits or receives a wireless signal in a corresponding frequency band. That is, when the battery 20 is installed on the electronic device 100, the electronic device 100 may perform NFC with another electronic device through the NFC antenna device. Although the above description was given for an NFC antenna device, an embedded antenna device for Wi-Fi communication and Bluetooth communication, may be further installed in the battery 20.

As will be described below, the battery 20 may be charged from a separate charging device. The charging device may be applied to a wire charging method using a Travel Adaptor (TA) charger and Universal Serial Bus (USB). The charging device may also be applied to a wireless charging method using a microwave method, a magnetic induction method, or a resonance method.

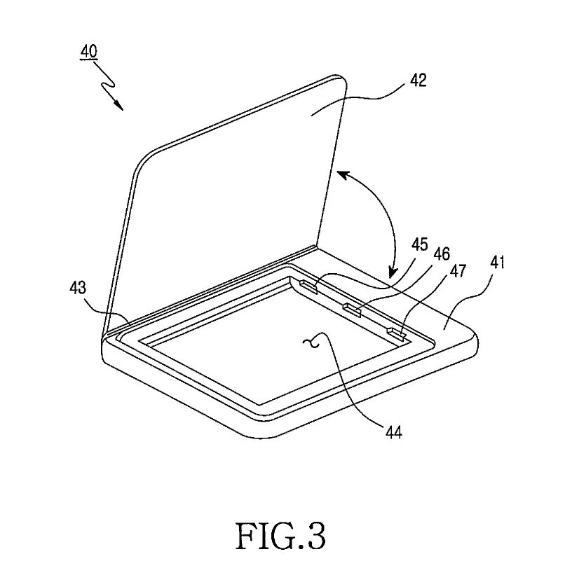

FIG. 3 is a perspective view illustrating a structure of a charging device according to an embodiment of the present invention.

Referring to FIGS. 1 and 3, the charging device 40 includes a housing 41 for receiving the battery 20, a cover 42 which opens at a certain angle from the housing 41, and a connection part 43 installed to allow the cover 42 to rotate at the certain angle. The cover 42 may be omitted.

The housing 41 has a battery receiving groove 44 for receiving the battery 20. Recesses 45 to 47 may be formed in positions corresponding to the plurality of mounting projections 231 to 233 which protrude at a certain interval on the second support 23 of the battery 20. Accordingly, when the battery 20 is mounted on the battery receiving groove 44, the mounting projections 231 to 233 of the battery 20 may be fixed by the recesses 45 to 47 formed in corresponding positions of the battery receiving groove 44 of the housing 41.

The cover 42 is installed to rotate at a certain angle from the housing 41, and is disposed on an upper surface of the housing 41. A space may be formed to easily pull the battery 20 from the battery receiving groove 44 when the cover 42 is open.

Although not shown in FIG. 3, a circuit board may be installed in an internal space of the housing 41 of the charging device 40. The circuit board includes a basic circuit and a plurality of electronic devices. The circuit board charges the battery 20 and detects a charging level of the battery 20.

The circuit board includes a communication module for wireless communication with the electronic device 100. For example, the charging device 40 may perform local-area communication with the electronic device 100 through an NFC module of the circuit board. Herein, the charging device 40 uses an NFC antenna device installed in the battery 20 without having a separate antenna device. In this case, although the cover 42 of the charging device 40 is closed, because a thickness of the cover 42 is thin, the charging device 40 may still perform NFC.

The charging device 40 may also have an NFC antenna device therein. For example, the NFC antenna device may be installed in the cover 42 of the charging device 40. The NFC antenna device may include an external antenna device exposed to the outside. The NFC antenna device installed in the charging device 40 may be also be, but is not limited to, at least one of a microstrip patch antenna device and an embedded antenna device of a plate structure such as a PIFA device. However, the embedded antenna device may be at least one of antenna devices of various types, such as a dipole antenna device, a monopole antenna device, a helical antenna device and a loop antenna device.

In accordance with an embodiment of the present invention, the charging device 40 described above provides the housing 41 and the cover 42 which rotate in a folded type. However, the charging device 40 may include at least two housings which are configured by types such as a sliding type, a pop-up type, and a swivel type.

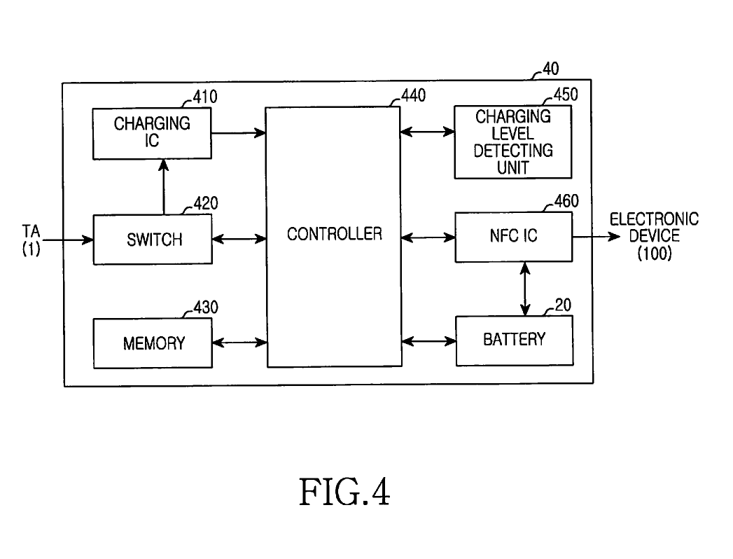

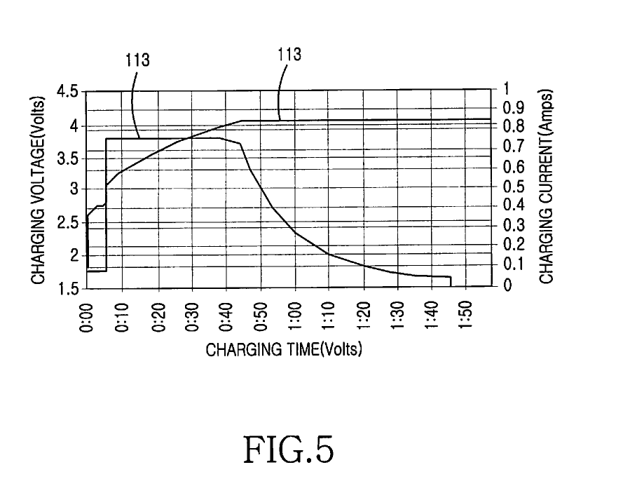

FIG. 4 is a block diagram illustrating configuration of a charging device for charging a battery according to an embodiment of the present invention. FIG. 5 is a graph of charging progress of a charging device according to an embodiment of the present invention.

Referring to FIGS. 3 and 4, the charging device 40 includes a charging Integrated Circuit (IC) 410, a switch 420, a memory 430, a controller 440, a charging level detecting unit 450, an NFC IC 460, and a battery 20.

The switch 420 supplies or blocks voltage supplied from a TA 1 (e.g., a TA charger or USB) to the charging IC 410 according to control of the controller 440. For example, when a charging stop signal is received from the controller 440, the switch 420 blocks voltage supplied from the TA 1 from being supplied to the charging IC 410 by releasing a connection between the TA 1 and the charging IC 410. When a charging resuming signal is received from the controller 440, the switch 420 supplies voltage from the TA 1 to the charging IC 410 by connecting the TA1 with the charging IC 410.

The charging IC 410 may convert the voltage supplied from the TA 1 into a suitable voltage (or a buffered voltage) for charging in the battery 20. The charging IC 410 may be designed to operate by receiving a charging signal of the controller 440.

The controller 440 controls charging of the battery 20 using at least one software program and controls the memory 430 to store a charging level of the battery 20. The controller 440 may also recognize the mounting of the battery 20. When the battery 20 is installed in the charging device 40, the controller 440 may activate the NFC IC 460 using an NFC antenna installed in the battery 20.

In accordance with an embodiment of the present invention, the controller 440 provides battery charging information stored in the memory 430 to an electronic device. The controller 440 performs wireless communication with the electronic device through the NFC IC 460. At this time, the controller 440 performs a control operation to use the NFC antenna installed in the installed battery 20. The controller 440 controls an operation mode of the NFC IC 460 and includes instructions corresponding to the operation mode.

The charging level detecting unit 450 detects a charging capacity of the battery 20 and provides the detected charging capacity to the controller 440. The charging level detecting unit 450 may detect a charging level of the battery 20 using a fuel gauge type or a capacity table value using a charging voltage and current. For example, as shown in FIG. 5, when using the capacity table value using the charging voltage and current, the charging voltage is maintained as a certain voltage value after a certain time period elapses, while its voltage value was increased as the charging time is started. The charging current may start to be reduced from a time point where a certain voltage value is maintained as at a constant value, after being uniformly maintained as a certain current value until that time point. Accordingly, the charging level detecting unit 450 detects a charging level based on this capacity table value.

In accordance with an embodiment of the present invention, FIG. 5 illustrates, but is not limited to, a charging graph of a general linear charger. Capacity table values using voltage and current may be defined by repeatedly simulating capacity according to a charging voltage and a charging current. In addition to the above-described type, there are various types for detecting a charging capacity.

The NFC IC 460 includes a software component for providing battery charging information using local-area communication with the electronic device. For example, the NFC IC 460 may perform local-area communication with the electronic device and provide battery charging information stored in the memory 430 of the charging device 40. As described above, a state where the NFC IC 460 provides battery charging information may be referred to as a card mode. Also, the NFC IC 460 may perform a control operation such that the electronic device acquires battery charging information stored in the memory 430 of the charging device 40 using local-area communication. As described above, a state where the NFC IC 460 guides the electronic device to acquire battery charging information may be referred to as a read mode. The NFC IC 460 may use an NFC antenna device installed in the battery 20 to perform local-area communication. The NFC IC 460 may include a related process for controlling the above-described read or card mode and various routines for supporting NFC operation.

The memory 430 includes a plurality of software for performing a smooth operation of the controller 440. For example, the controller 440 may execute a charging control program stored in the memory 430, provide a charging signal to the charging IC 410, and control the memory 430 to store the battery charging information detected in the charging level detecting unit 450. In addition, the memory 430 may further store an instruction for supplying power of the charging device 40.

In accordance with an embodiment of the present invention, the charging device 40 includes, but is not limited to, the NFC IC 460 for wireless communication with the electronic device. For example, when the charging device 40 has various wireless communication modules, it may perform data communication through various wireless communication methods (e.g., a Wi-Fi communication method, a Bluetooth communication method, etc.).

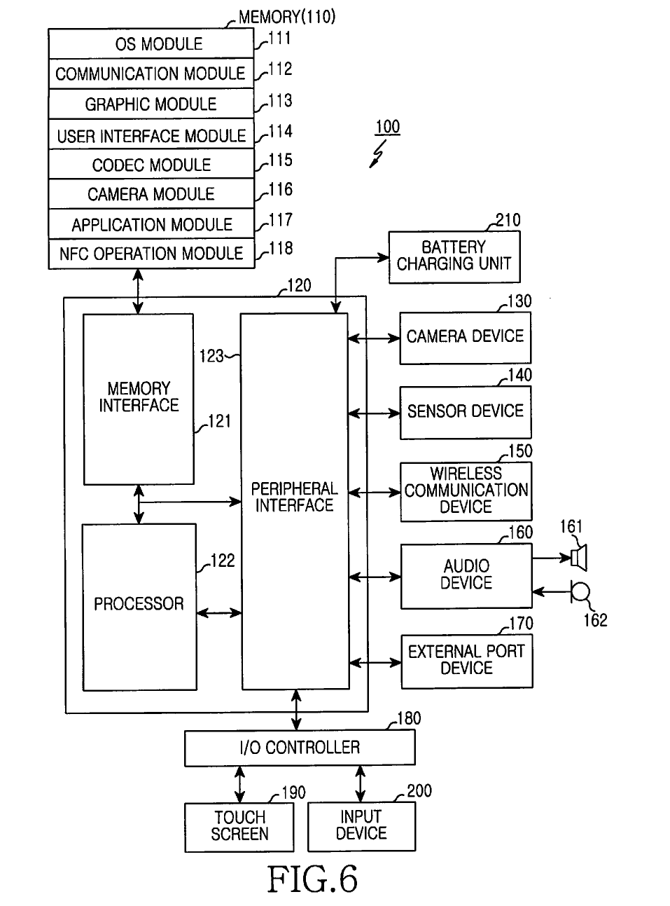

FIG. 6 is a block diagram illustrating configuration of an electronic device according to an embodiment of the present invention;

Referring to FIG. 6, the electronic device 100 includes a memory 110, a processor unit 120, a camera device 130, a sensor device 140, a wireless communication device 150, an audio device 160, an external port device 170, an Input/Output (I/O) controller 180, a touch screen 190, an input device 200, and a battery charging unit 210. Also, the memory 110 and the external port device 170 may be a plurality of memories and external port devices, respectively.

The processor unit 120 includes a memory interface 121, at least one processor 122, and a peripheral interface 123. The memory interface 121, at least the one processor 122, and the peripheral interface 123 may be integrated in at least one Integrated Circuit (IC) or be separately configured.

The memory interface 121 allows the processor 122 or the peripheral interface 123 to access the memory 110.

The peripheral interface 123 controls connection among an input and output peripheral of the electronic device 100, the processor 122, and the memory interface 121.

The processor 122 provides various multimedia services using at least one software program. Herein, the processor 122 executes at least one program stored in the memory 110 and provides a service corresponding to the corresponding program.

The processor 122 executes several software programs and performs several functions for the electronic device 100. The processor 122 performs process and control for audio, video, and data communication. The processor 122 interworks with software modules stored in the memory 110 and performs various embodiments of the present invention.

In accordance with an embodiment of the present invention, the processor 122 compares the charging remaining capacity of a battery installed in the electronic device 100 with a charging level of a battery which is being charged in a charging device, which is received from the charging device through local-area communication. In addition, the processor 122 outputs the charging remaining capacity of the battery installed in the electronic device 100 and the charging level of the battery which is being charged in the charging device.

The processor 122 may include one or more data processors, an image processor, or a codec. In addition, the electronic device 100 may separately include the data processor, the image processor, or the codec.

The camera device 130 performs a camera function such as a photo and video clip recording function. The camera device 130 may include a Charge Coupled Device (CCD) or a Complementary Metal-Oxide Semiconductor (CMOS) device. Also, the camera device 130 may change hardware-like configurations of the electronic device 100, for example, may adjust lens movement, the number of diaphragms, etc. according to a camera program executed by the processor 122. The sensor device 140 may include a proximity sensor, a Hall sensor, an illumination sensor, a motion sensor, etc. The proximity sensor senses an object approaching the electronic device 100. The Hall sensor senses magnetism of a metal body. The illumination sensor senses light around the electronic device 100. The motion sensor may sense motion of the electronic device 100.

The wireless communication device 150 performs wireless communication and includes a radio frequency transceiver or a beam (e.g., infrared ray) transceiver. The wireless communication device 150 may operate through one or more of a Global System for Mobile communication (GSM) network, an Enhanced Data GSM Environment (EDGE) network, a Code Division Multiple Access (CDMA) network, a W-CDMA network, a Long Term Evolution (LTE) network, an Orthogonal Frequency Division Multiple Access (OFDMA) network, a Wireless Fidelity (Wi-Fi) network, a WiMax network, a Near Field Communication (NFC) network, and a Bluetooth network.

The audio device 160 connects to the speaker 161 and the microphone 162 and is responsible for audio input and output, such as a voice recognition function, a voice copy function, a digital recording function, and a phone call function. The audio device 160 provides an audio interface between a user and the electronic device 100. The audio device 160 receives a data signal from the processor unit 120, converts the received data signal into an electric signal, and outputs the converted electric signal through the speaker 161.

The speaker 161 converts a band of an electric signal into an audible frequency band and outputs the converted signal. The speaker 161 may be disposed in a front or rear surface of the electronic device 100. The speaker 161 may include a flexible film speaker in which at least one piezoelectric material is attached to one vibration film.

The microphone 162 converts a sound wave transmitted from people or other sound sources into an electric signal. The audio device 160 receives the electric signal from the microphone 162, converts the received electric signal into an audio data signal, and transmits the converted audio data signal to the processor unit 120. The audio device 160 may include an attachable and detachable earphone, headphone, or headset.

The external port device 170 connects the electronic device 100 to a counterpart electronic device directly or connects it to the counterpart electronic device indirectly through a network (e.g., the Internet, an intranet, a wireless Local Area Network (LAN), etc.).

The I/O controller 180 provides an interface between an I/O device, such as the touch screen 190 and the input device 200, and the peripheral interface 123.

The touch screen 190 provides an input/output interface between the electronic device 100 and the user. For example, the touch screen 190 may transmit touch input of the user to the processor unit 120 and show visual information, texts, graphics, videos, etc., provided from the processor 120, to the user by applying touch sensing technologies.

The touch screen 190 displays state information of the electronic device 100, characters input by the user, moving pictures, still pictures, etc. The touch screen 190 also displays information of an application executed by the processor 122.

The touch screen 190 may be further applied to not only capacitive, resistive, infrared ray, and surface acoustic wave technologies but also certain multi-touch sensing technologies including a proximity sensor array or other elements. The touch screen 190 may be at least one of a Liquid Crystal Display (LCD), an Organic Light Emitting Diode (OLED), an Active Matrix Organic Light Emitting Diode (AMOLED), a flexible display, and a three-dimensional display.

The input device 200 provides input data generated by a selection of the user to the processor unit 122 through the I/O controller 180. Herein, the input device 200 may include a keypad including at least one hardware button, a touch pad for sensing touch information, etc. The input device 200 may include an up/down button for volume control. In addition, the input device 200 may include at least one of pointer devices, such as a push button having a corresponding function, a locker button, a locker switch, a thumb-wheel, a dial, a stick, and a stylus pen.

The battery charging unit 210 charges the battery installed in the electronic device 100 and detects the charging remaining capacity of the battery. The battery charging unit 210 may be applied to a wire charging method using a TA charger and USB. The battery charging unit 210 may also be applied to a wireless charging method using a microwave method, a magnetic induction method, or a resonance method. The battery charging unit 210 provides the charging remaining capacity of the battery, which is detected through a gauge, to the processor 122.

The memory 110 includes a high-speed Random Access Memory (RAM) such as one or more magnetic storages, a non-volatile memory, one or more optical storages, or a flash memory (e.g., a NAND flash memory or a NOR flash memory). The memory 110 stores software components, which include an Operating System (OS) module 111, a communication module 112, a graphic module 113, a user interface module 114, a CODEC module 115, a camera module 116, an application module 117, and an NFC operation module 118. Also, the term “modules” may be expressed in a set of instructions, an instruction set, or programs.

The OS module 111 may include an embedded OS such as Windows, Linux, Darwin, RTXC, UNIX, OS X, or VxWorks and include several software components for controlling the general system operation. Control of the general system operation includes memory control and management, storage hardware (device) control and management, power control and management, etc. The OS module 111 also performs a function for smoothly communicating between several hardware components (devices) and software components (modules).

The communication module 112 communicates with at least one of counterpart electronic devices such as a computer, a server, and an electronic device through the wireless communication device 150 or the external port device 170.

The graphic module 113 includes several software components for providing and displaying graphics on the touch screen 190. The term “graphics” means texts, web pages, icons, digital images, videos, animations, etc.

The user interface module 114 includes several software components related to a user interface. The user interface module 114 controls the touch screen 190 to display information of an application executed by the processor 122. Also, the user interface module 114 includes contents about whether a state of a user interface has been changed to any state, whether a state of a user interface has been changed in any condition, etc.

The CODEC module 115 includes software components related to encoding and decoding of video files.

The camera module 116 includes cameral-related software components which may perform camera-related processes and functions.

The application module 117 includes a software component for at least one application installed in the electronic device 100. This application includes a browser application, an email application, a phonebook application, a game application, a short message service application, a multimedia message service application, a Social Network Service (SNS) application, an instant message application, a wake-up call application, an MP3 application, a scheduling application, a camera application, a word processing application, a keyboard emulation application, an address book application, a touch list application, a widget application, a Digital Rights Management (DRM) application, a voice recognition application, a voice copy application, a position determining application, a location based service application, etc.

In particular, the NFC operation module 118 includes a software component for receiving or acquiring battery charging information using NFC with the charging device 40. For example, there is a read mode which is a state where the NFC operation module 118 receives battery charging information from the charging device using local-area communication. There is a card mode which is a state where the NFC operation module 118 acquires battery charging information stored in a memory of the charging device using local-area communication. The NFC operation module 118 includes a related process for controlling the above-described read or card mode and various routines for supporting an NFC operation.

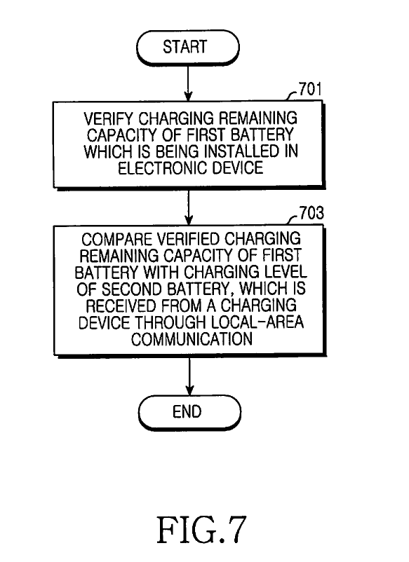

FIG. 7 is a flowchart illustrating an operation process of an electronic device according to an embodiment of the present invention.

Referring to FIG. 7, the electronic device 100 verifies the charging remaining capacity of a first battery which is installed therein in step 701. In accordance with an embodiment of the present invention, the electronic device receives the charging remaining capacity of the first battery, which is detected in a battery charging unit 210.

The electronic device 100 compares the verified charging remaining capacity of the first battery with a charging level of a second battery, which is received from a charging device through local-area communication, in step 703. For example, the second battery is being charged in the charging device 40 and the charging level of the second battery is verified by the charging device 40. The electronic device receives a charging level of the second battery through any one of local-area communications with the charging device 40, such as NFC, Wi-Fi communication, and Bluetooth communication.

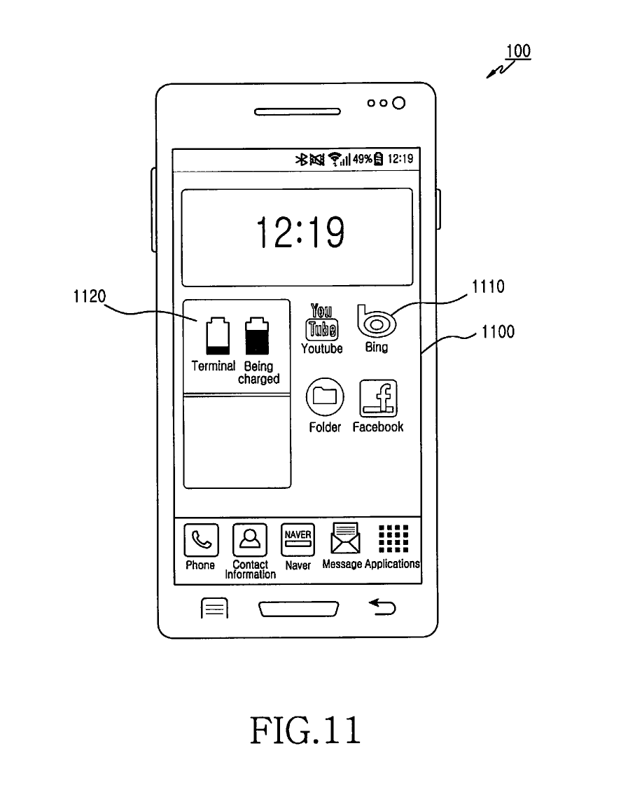

The electronic device 100 may output the charging remaining capacity of the first battery and the charging level of the second battery as at least one of vibration data, Light Emitting Diode (LED) data, text data, image data, and voice data. As shown in FIG. 11, the electronic device 100 may display a battery icon 1120 on a region of a touch screen 1100 which displays a plurality of objects 1110. For example, a user of the electronic device may visually verify the charging remaining capacity of the first battery and a charging level of the second battery through the battery icon 1120. Although it is not shown in FIG. 11, the electronic device may further display the remaining time to a full capacity of the second battery. This battery icon 1120 may be displayed on, but is not limited to, a basic setting screen of the electronic device, and also may be displayed on at least one of various screens.

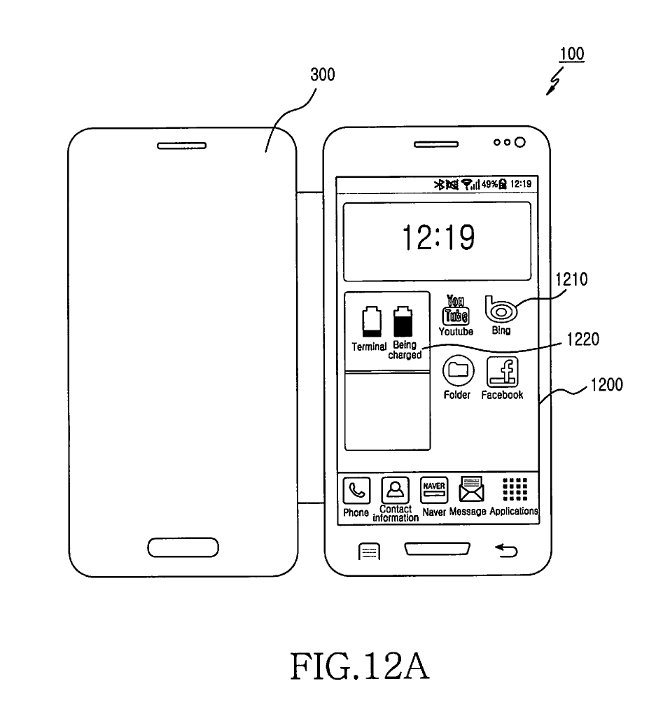

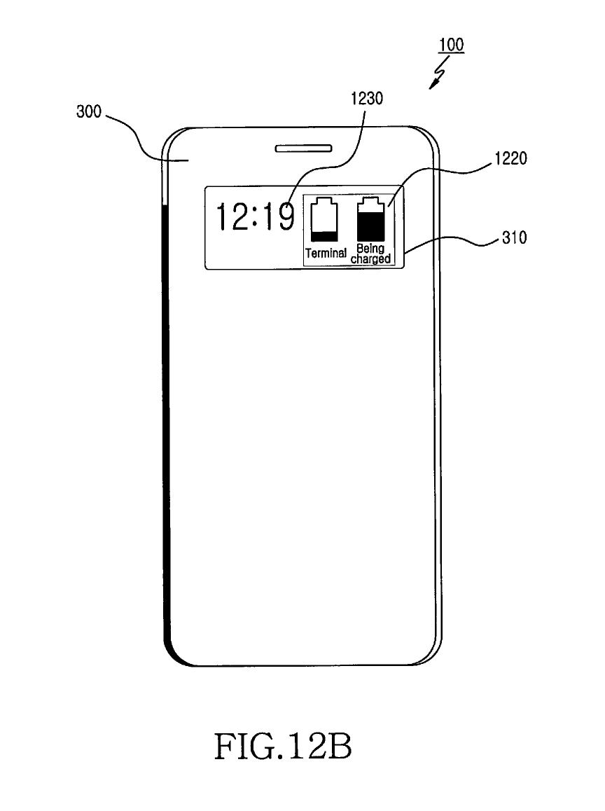

In accordance with one embodiment of the present invention, as shown in FIGS. 12A and 12B, a battery icon 1220 may be applied to an electronic device which has an openable flip cover 300. As seen in FIG. 12A, the battery icon 1220 may be displayed on a region of a touch screen 1200 which displays a plurality of objects 1210. Also, as seen in FIG. 12B, when the flip cover 300 is closed, the electronic device may be configured such that the user may see a current time 1230 and the battery icon 1220 through a transparent window 310 disposed in a front surface of the flip cover 300. Also, the electronic device may be configured such that the user may see various objects through the transparent window 310 of the flip cover 300, and the window 310 can be located at other regions of the flip cover 300 to display other objects.

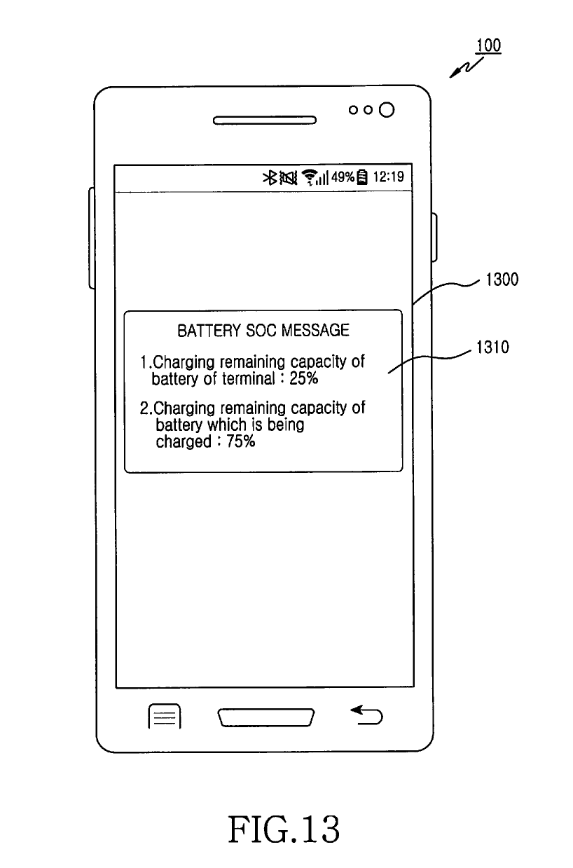

In accordance with one embodiment of the present invention, the electronic device may output the charging remaining capacity of the first battery and a charging level of the second battery as a pop-up type window. As shown in FIG. 13, the electronic device displays a battery SoC message 1310 on a touch screen 1300. The battery SoC message 1310 may include contents about the charging remaining capacity of the first battery which is installed in the electronic device and a charging level of the second battery which is being charged in the charging device. Although it is not shown in FIG. 13, the electronic device may further display the remaining time to a full capacity of the second battery.

An instruction set for the operations of the present invention may be stored as one or more modules in the above-described memory. In this case, the modules stored in the memory may be executed by one or more processors.

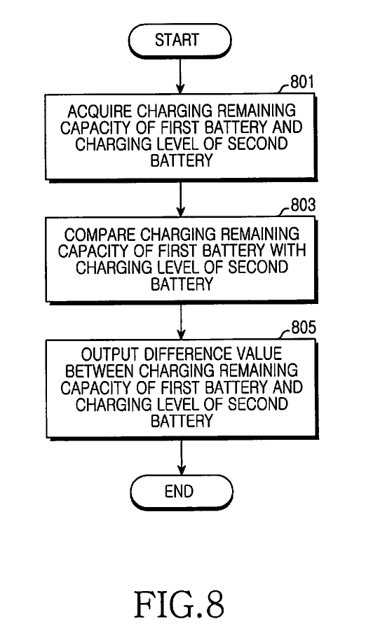

FIG. 8 is a flowchart illustrating an operation process of an electronic device according to another embodiment of the present invention.

Referring to FIG. 8, the electronic device 100 acquires the charging remaining capacity of a first battery and a charging level of a second battery in step 801. Herein, the first battery refers to a battery installed in the electronic device 100 and the second battery refers to a battery which is charged in a charging device 40.

The electronic device receives the charging remaining capacity of the first battery, which is detected by the battery charging unit 210. The electronic device 100 receives a charging level of the second battery, which is detected by a charging level detecting unit 450 of the charging device 40. For example, the electronic device 100 may receive a charging level of the second battery through any one of local-area communications with the charging device, such as NFC, Wi-Fi communication, and Bluetooth communication.

The electronic device 100 compares the charging remaining capacity of the first battery with the charging level of the second battery in step 803. For example, a processor may extract a difference value between the charging remaining capacity of the first battery and the charging level of the second battery and determine whether the charging remaining capacity of the first battery is greater than the charging level of the second battery.

The electronic device 100 outputs the difference value between the charging remaining capacity of the first battery and the charging level of the second battery in step 805. The difference value between the charging remaining capacity of the first battery and the charging level of the second battery may be output as at least one of vibration data, LED data, text data, image data, and voice data. For example, this difference value may be configured as a pop-up type window which is visually displayed. Although it is not shown in FIG. 8, the electronic device may further display the remaining time to a full capacity of the second battery.

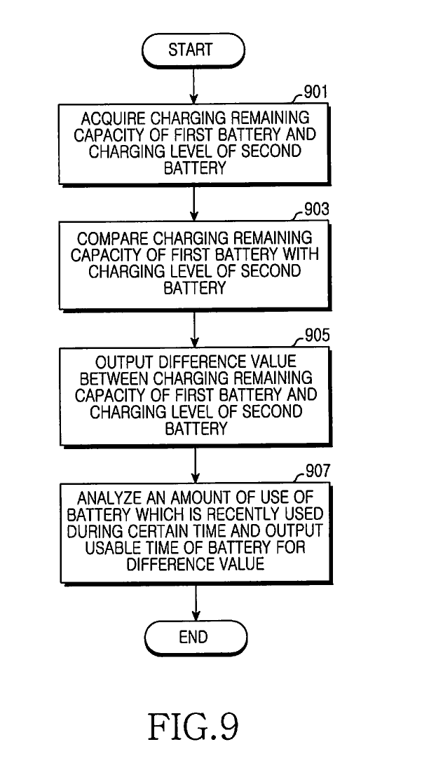

FIG. 9 is a flowchart illustrating an operation process of an electronic device according to another embodiment of the present invention.

Referring to FIG. 9, the electronic device 100 acquires the charging remaining capacity of a first battery and a charging level of a second battery in step 901.

The electronic device 100 receives the charging remaining capacity of the first battery, which is detected by a battery charging unit 210. The electronic device 100 receives a charging level of the second battery, which is detected by a charging level detecting unit 450 of the charging device 40. For example, the electronic device may receive a charging level of the second battery through any one of local-area communications with the charging device, such as NFC, Wi-Fi communication, and Bluetooth communication.

The electronic device 100 compares the charging remaining capacity of the first battery with the charging level of the second battery in step 903. For example, a processor may extract a difference value between the charging remaining capacity of the first battery and the charging level of the second battery and determine whether the charging remaining capacity of the first battery is greater than the charging level of the second battery.

The electronic device 100 outputs the difference value between the charging remaining capacity of the first battery and the charging level of the second battery in step 905. The difference value between the charging remaining capacity of the first battery and the charging level of the second battery may be output as at least one of vibration data, LED data, text data, image data, and voice data. For example, this difference value may be configured as a pop-up type window which is visually displayed. Although it is not shown in FIG. 9, the electronic device may further display the remaining time to a full capacity of the second battery.

The electronic device 100 analyzes an amount of use of a battery which is recently used during a certain time and output a useable time of the battery for the difference value in step 907.

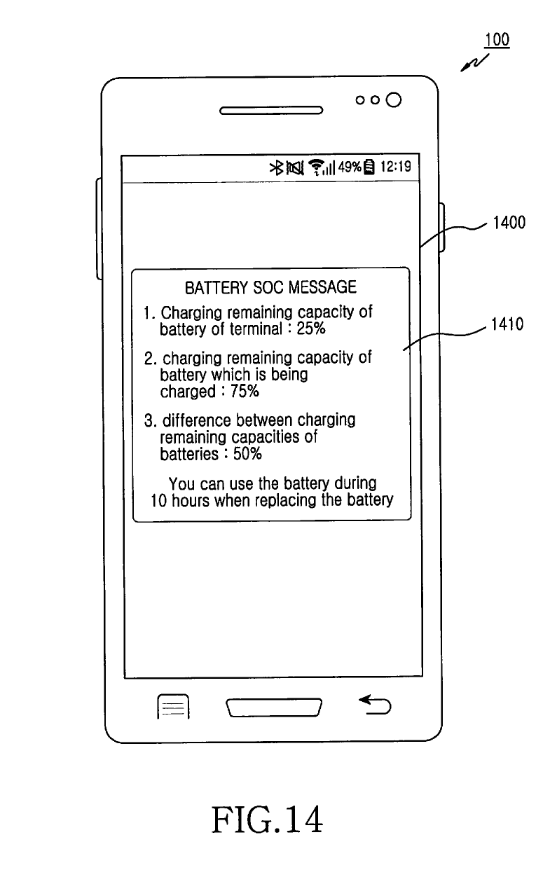

For example, the processor may detect an amount of use of a battery which is recently used during the previous 10 hours. When the first battery which is currently installed in the electronic device is replaced with the second battery, the processor may detect a usable time of the battery based on this amount of use of the battery. This usable time of the battery may be output as at least one of vibration data, LED data, text data, image data, and voice data. For example, as shown in FIG. 14, the usable time of the battery may be implemented as a pop-up type window on a touch screen 1400 by a battery SoC message 1410. The battery SoC message 1410 may include at least one of the charging remaining capacity of a battery which is currently installed in the electronic device 100, the charging remaining capacity of a battery which is being charged in the charging device 40, difference between charging remaining capacities of two batteries, and a usable time of a battery when the battery is replaced with the battery which is being charged in the charging device 40.

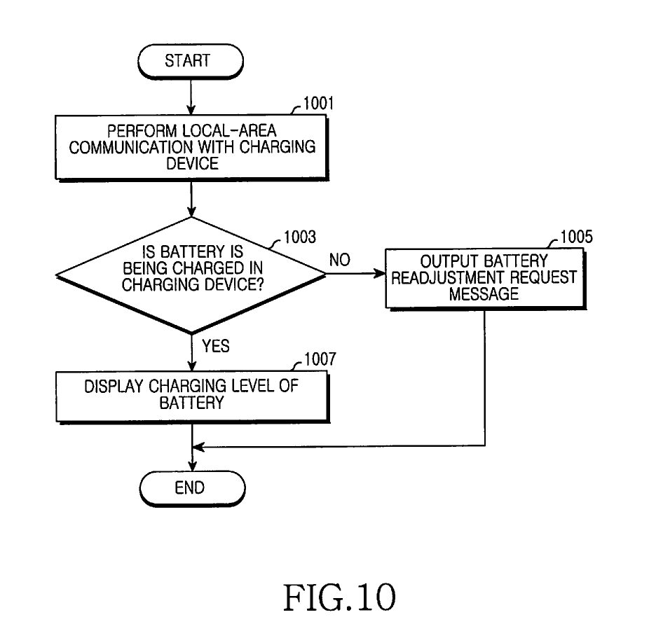

FIG. 10 is a flowchart illustrating an operation process of an electronic device according to another embodiment of the present invention.

Referring to FIG. 10, the electronic device 100 performs local-area communication with a charging device 40 in step 1001. Each of the electronic device 100 and the charging device 40 may have a communication module to perform local-area communication by any one of an NFC type, a Wi-Fi type, and a Bluetooth type.

The electronic device 100 determines whether a battery is being charged in the charging device 40 in step 1003. For example, the electronic device 100 may verify whether the battery is being charged in the charging device through the local-area communication with the charging device 40.

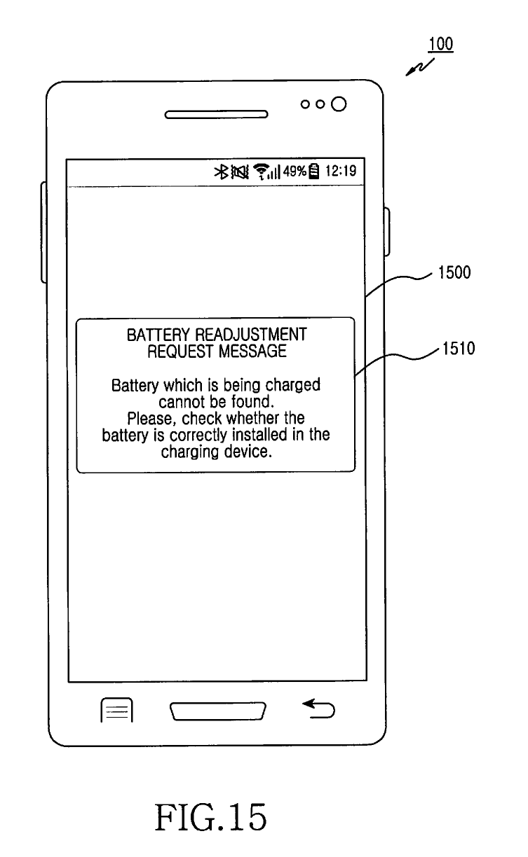

When the battery is not being charged in the charging device 40, the electronic device outputs a battery readjustment request message in step 1005. The battery readjustment request message may be output as at least one of vibration data, LED data, text data, image data, and voice data. For example, as shown in FIG. 15, the battery readjustment request message may be displayed as, but is not limited to, a pop-up window 1510. Also, the battery readjustment request message may be displayed on at least one of various screens of a touch screen 1500.

On the other hand, when the battery is being charged in the charging device 40, the electronic device displays a charging level of the battery in step 1007. The charging level of the battery may be output as at least one of vibration data, LED data, text data, image data, and voice data.

In accordance with the above-described various embodiments of the present invention, the electronic device may provide a user interface such that the user of the electronic device may intuitively verify an SoC of the battery.

In accordance with various embodiments of the present invention, respective modules may be configured by software, firmware, hardware, or the combination of them. Some or all of the modules may be configured in one entity and perform functions of the respective modules equally. In accordance with various embodiments of the present invention, respective operations may be executed successively, repeatedly, or in parallel. Also, some operations may be omitted, or may be executed by adding other operations. For example, respective operations may be executed by corresponding modules described in embodiments of the present invention.

Methods according to the claims of the present invention or embodiments described in the foregoing specification of the present invention may be implemented as hardware, software, or a combination of the hardware and the software.

When the method is implemented by the software, a computer-readable storage medium for storing one or more programs (software modules) may be provided. The one or more programs stored in the computer-readable storage medium are configured for being executed by one or more processors in an electronic device. The one or more programs include instructions for allowing an electronic device to execute the methods according to the claims of the present invention and/or the embodiments described in the specification of the present invention.

These programs (software module, software) may be stored in a Random Access Memory (RAM), a non-volatile memory including a flash memory, a Read Only Memory (ROM), an Electrically Erasable Programmable ROM (EEPROM), a magnetic disc storage device, a Compact Disc-ROM (CD-ROM), a Digital Versatile Disc (DVD) or an optical storage device of a different type, and a magnetic cassette. The programs may also be stored in a memory configured by a combination of some or all of them. The configured memory may include a plurality of memories.

Also, the programs may be stored in an attachable storage device capable of accessing an electronic device through each of communication networks such as the Internet, an intranet, a Local Area Network (LAN), a Wide LAN (WLAN), and a Storage Area Network (SAN) or a communication network configured by combination of them. This storage device may connect to the electronic device through an external port.

While the present invention has been particularly shown and described with reference to certain embodiments thereof, it will be understood by those skilled in the art that various changes in form and details may be made therein without departing from the spirit and scope of the present invention as defined by the appended claims.

What is claimed is:

1. A method in an electronic device, the method comprising:
verifying a charging remaining capacity of a first battery which is installed in the electronic device; and
comparing the verified charging remaining capacity of the first battery with a charging level of a second battery, which is received from a charging device through a local-area communication method,
wherein the second battery is being charged in the charging device, and
wherein the charging level of the second battery is verified by the charging device.

2. The method of claim 1, wherein the local-area communication method is any one of an NFC method, a Wi-Fi communication method, and a Bluetooth communication method.

3. The method of claim 2, wherein the charging level of the second battery is received through a read mode or card mode of the NFC method.

4. The method of claim 1, further comprising outputting the charging remaining capacity of the first battery and the charging level of the second battery as at least one of vibration data, LED data, text data, image data, and voice data.

5. The method of claim 1, wherein comparing the charging remaining capacity of the first battery with the charging level of the second battery comprises outputting a difference value comparing the charging remaining capacity of the first battery with the charging level of the second battery.

6. The method of claim 5, further comprising analyzing an amount of use of a battery which is recently used during a certain time and further outputting a usable time of the battery for the difference value.

7. The method of claim 1, wherein the charging device performs local-area communication with the electronic device using an antenna installed in the first battery.

8. The method of claim 1, wherein the charging device performs local-area communication with the electronic device using an antenna installed therein.

9. The method of claim 1, further comprising outputting a battery readjustment request message when the second battery is not being charged in the charging device.

10. The method of claim 9, wherein the battery readjustment request message is output as at least one of vibration data, LED data, text data, image data, and voice data.

11. An electronic device comprising:
a battery charging unit for verifying a charging remaining capacity of a first battery which is installed in the electronic device;
a wireless communication device for receiving a charging level of a second battery from a charging device through a local-area communication method; and
a processor for comparing the verified charging remaining capacity of the first battery with the received charging level of the second battery,
wherein the second battery is being charged in the charging device, and
wherein the charging level of the second battery is verified by the charging device.

12. The electronic device of claim 11, wherein the local-area communication method is any one of an NFC method, a Wi-Fi communication method, and a Bluetooth communication method.

13. The electronic device of claim 12, wherein the charging level of the second battery is received through a read mode or card mode of the NFC method.

14. The electronic device of claim 11, wherein the processor outputs the charging remaining capacity of the first battery and the charging level of the second battery as at least one of vibration data, LED data, text data, image data, and voice data.

15. The electronic device of claim 11, wherein the processor outputs a difference value of comparing the charging remaining capacity of the first battery with the charging level of the second battery.

16. The electronic device of claim 15, wherein the processor analyzes an amount of use of a battery which is recently used during a certain time and further outputs a usable time of the battery for the difference value.

17. The electronic device of claim 11, wherein the charging device performs local-area communication with the electronic device using an antenna installed in the first battery.

18. The electronic device of claim 11, wherein the charging device performs local-area communication with the electronic device using an antenna installed therein.

19. The electronic device of claim 11, wherein the processor outputs a battery readjustment request message when the second battery is not being charged in the charging device.

20. The electronic device of claim 19, wherein the battery readjustment request message is output as at least one of vibration data, LED data, text data, image data, and voice data.
